(19) United States
(12) Patent Application Publication
(10) Pub. No.: US 2006/0227517 A1
(43) Pub. Date: Oct. 12, 2006

(54) Modified connector for improved manufacturing and testing

(75) Inventors: Fernando A. Zayas, Loveland, CO (US); Richard G. Ramsdell, Saratoga, CA (US)

Correspondence Address: FLIESLER MEYER, LLP, FOUR EMBARCADERO CENTER, SUITE 400, SAN FRANCISCO, CA, 94111, US

(73) Assignee: Matsushita Electric Industrial Co., Ltd., Osaka (JP)

(21) Appl. No.: 11/092,195

(22) Filed: Mar. 29, 2005

(51) Int. Cl. H05K 7/00

(52) U.S. Cl. 361/748

(57) ABSTRACT

Embodiments of the present invention relate to systems, methods, and computer readable media for transmitting data to and from a rotatable storage medium. A hard drive configured for embedding in a portable device is configured with a standardized connection to enable easy interoperability between embedded storage devices and portable computers. The hard drive is augmented with additional connection pins that can be used for manufacturing processes. These pins enable testing instructions to be passed between a testing system and the hard drives in a cost effective manner, while not requiring any changes in end-user products that utilize the hard drives.

### FIELD OF THE INVENTION

The present invention relates generally to connections for storage devices. The present invention relates more specifically to augmenting the connections for storage devices to aid in manufacturing processes.

### BACKGROUND OF THE INVENTION

Over the past ten years, the mass production of storage devices has become both increasingly large in scale and increasingly competitive. The combination of aggressive computer upgrade schedules, increased storage demands driven by media applications, and the opening of foreign markets to computer sales has driven up the size and scale of storage device production. However, at the same time, increased competition has driven down the cost of computer components such as storage devices. This combination of increased scale and cost-reduction pressures has increased the importance of production efficiency.

While once used primarily in personal and enterprise computers that were stored in fixed locations and moderate temperatures, hard drives are now appearing in a wide range of portable devices, such as laptop computers, personal data assistants, personal media players, and digital camcorders.

To reduce costs for the makers of the portable devices and to insure easy interoperability between different hard drives, standardized interfaces for connecting embedded hard drives to the portable devices have been developed. While such interoperability is useful, hard drive manufacturers may need additional connections for manufacturing and configuration processes. What is needed is a supplemented connector for that can be used for manufacturing and configuration while still allowing the hard drive to use standardized connections in end user products.

### BRIEF DESCRIPTION OF THE DRAWINGS

FIG. 1 is a block diagram illustrating a testing apparatus in accordance with one embodiment of the present invention.

FIG. 2 is a block diagram illustrating a more detailed view of a hard drive in accordance with one embodiment of the present invention.

FIG. 3 is a diagram illustrating a more detailed view of an actuator assembly in accordance with one embodiment of the present invention.

FIG. 4A is diagram illustrating a closer view of the connection between an array interface and a hard drive in accordance with one embodiment of the present invention.

FIG. 4B is a diagram illustrating one embodiment of a connection between an array interface carrier board and a test array.

FIGS. 5A-5D illustrate various embodiments of a flexible ribbon and connector for linking a hard drive and an array interface.

### DETAILED DESCRIPTION

Embodiments of the present invention relate to systems, methods, and computer readable media for transmitting data to and from a rotatable storage medium. A hard drive, as an example of a rotating media storage device, configured for embedding in a portable device is configured with a standardized connection to enable easy interoperability between embedded storage devices and portable computers. The hard drive is augmented with additional connection pins that can be used for manufacturing processes. These pins enable additional hardware to be available to the rotating media device during the manufacturing test process, for engineering development, and for failure analysis.

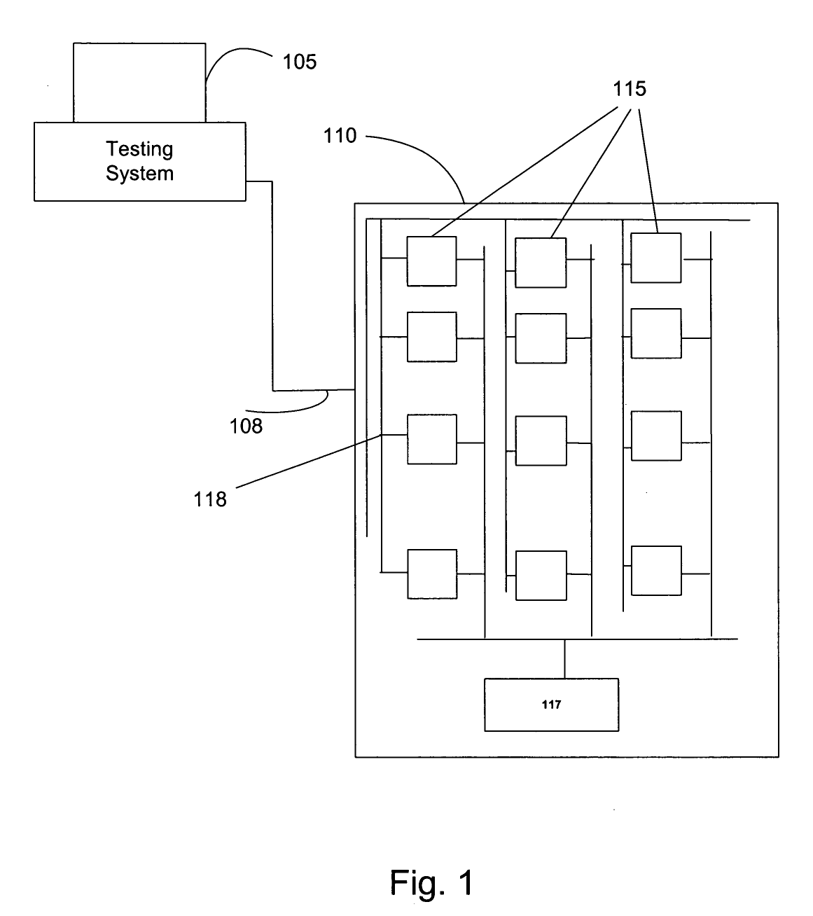

FIG. 1 is a block diagram illustrating an overview of an exemplary system for testing hard drives. The system includes a testing system 105. The testing system 105 may be a conventional computer or a computer configured specially for the purposes of storage device testing. The testing system 105 is configured to transmit testing instructions to an array 110 of hard drives 115 through an interface 108 and to receive feedback from the tested hard drives 115. The hard drives are powered through a power supply 117 connected to the array. Each hard drive has at least two connections, one for data transfer and one for power.

The hard drive array 110 includes multiple hard drives 115 that are connected to the array through one or more serial ports 108, Integrated Drive Electronics (IDE) ports, an infrared wireless connection (e.g. IRDA) or some manner of proprietary connection. In the present embodiment, the hard drives 115 are new drives that have been designated for post-production assembly testing.

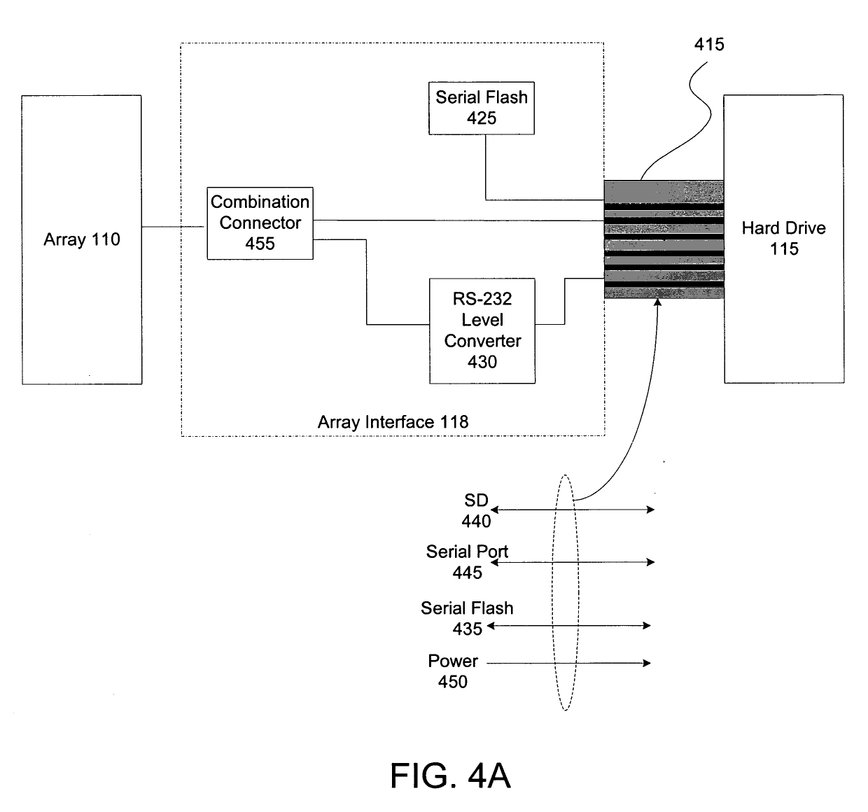

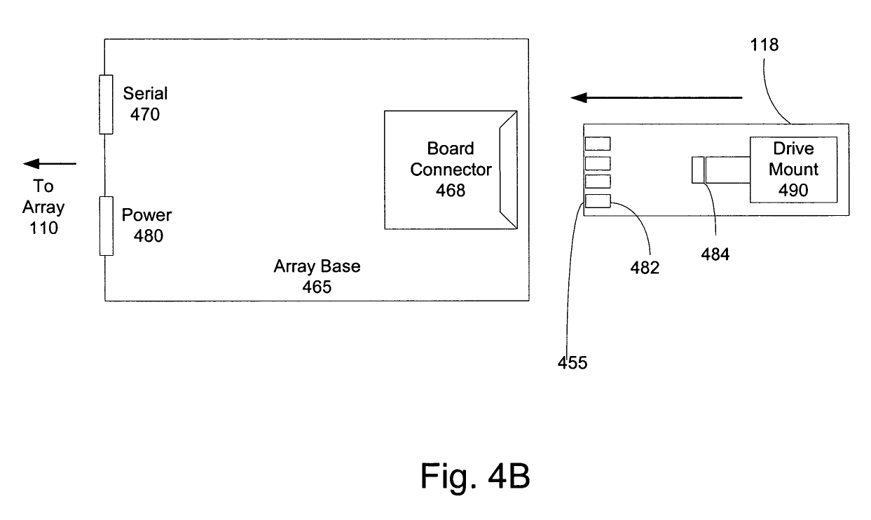

In one embodiment, each hard drive is mounted on an array interface board 118. The array interface board 118, which is discussed in greater detail with respect to FIG. 4A and FIG. 4B, includes a serial port for transmitting instructions between the testing computer 105 and the hard drive 115. The array interface board additionally includes flash memory. The flash memory can be used to store the results of tests run on the hard drives and for other purposes. The array interface board can also include a standard data transfer interface such as an Integrated Drive Electronics (IDE) interface, a Secure Digital Input/Output interface, or a MultiMedia Card (MMC) interface. In this embodiment, the array interface board includes an SDIO interface and an RS-232 serial interface.

In an alternate embodiment, the hard drives are drives that have been returned for additional diagnostics such as failure analysis. The hard drives 115 perform a series of diagnostic tests that are received from the testing system 105 or stored internally in the hard drives 115. The test system 105 gathers output from the hard drives 115 through the serial ports 108.

In some embodiments, the testing system 105 is not connected to an array, but is a user system (e.g. computer in public or private use) which is performing diagnostics on its own internal storage device or a single external hard drive. In those embodiments, the interface 108 can be a standard host to storage interface such as an Integrated Drive Electronics (IDE) or a Secure Digital Input/Output interface. The diagnostics can include tests to predict potential failures of the storage devices 115.

In additional embodiments, the hard drives are connected to the array 110 initially and instructions are downloaded from the test system 105 to the hard drives 115 through the serial ports 108. The test system 105 is then disconnected and the hard drives 115 run the tests in the array 110, which in one embodiment take 20-30 hours. A system such as the test system 105 can then be reconnected to the array 110, which receives the test results from the hard drives 115. The test results are used to sort the hard drives, with the better performing drives being passed forward to the next manufacturing stage and the weaker performing drives being returned for further testing or rework.

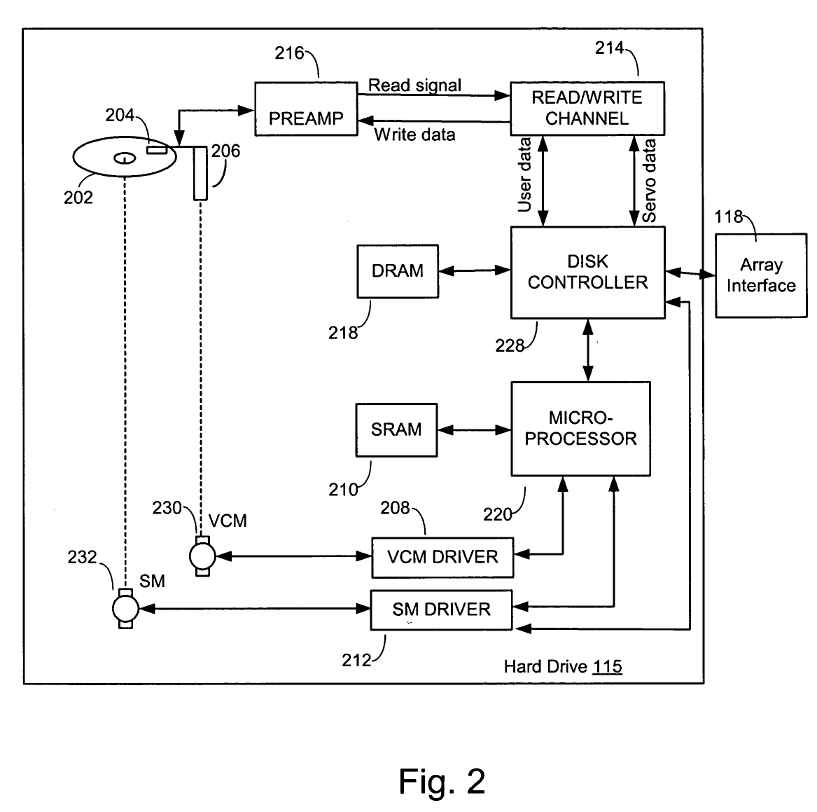

FIG. 2 shows a more detailed view of a storage device 115, which includes at least one rotatable storage medium 202 (i.e., disk) capable of storing information on at least one of its surfaces. In a magnetic disk drive as described below, the storage medium 202 is a magnetic disk. The numbers of disks and surfaces may vary from disk drive to disk drive. A closed loop servo system, including an actuator assembly 206, can be used to position a head 204 over selected tracks of the disk 202 for reading or writing, or to move the head 204 to a selected track during a seek operation. In one embodiment, the head 204 is a magnetic transducer adapted to read data from and write data to the disk 202. In another embodiment, the head 204 includes separate read and write elements. For example, the separate read element can be a magnetoresistive head, also known as an MR head. It will be understood that various head configurations may be used with embodiments of the present invention, including the characteristic that the read positions and write positions of the head differ and must be calibrated and that the method of recording and playback of the storage medium may be optical.

A servo system can include a voice coil motor driver 208 to drive a voice coil motor (VCM) 230 for rotation of the actuator assembly 206, a spindle motor driver 212 to drive a spindle motor 232 for rotation of the disk 202, a microprocessor 220 to control the VCM driver 208 and the spindle motor driver 212, and a disk controller 228 to accept information from a test system through the array interface 118 and to control many disk functions. When embedded within a device, the hard drive receives commands from a host. The host can be any device, apparatus, or system capable of utilizing the storage device 115, such as a personal computer, cellular phone, or Web server. In one embodiment, the host is the test system 105. The disk controller 228 can include an interface controller in some embodiments for communicating with the test system 105 or another host, and in other embodiments a separate interface controller can be used. Servo fields on the disk 202 are used for servo control to keep the head 204 on track and to assist with identifying proper locations on the disk 202 where data is written to or read from. When reading servo fields, the head 204 acts as a sensor that detects position information to provide feedback for proper positioning of the head 204 and for determination of the rotational position of the disk 202 via wedge numbers or other position identifiers.

The microprocessor 220 can also include a servo system controller, which can exist as circuitry within the drive or as an algorithm resident in the microprocessor 220, or as a combination thereof. In other embodiments, an independent servo controller can be used. Additionally, the microprocessor 220 may include some amount of memory such as SRAM, or an external memory such as SRAM 210 can be coupled with the microprocessor 220. The disk controller 228 can also provide user data to a read/write channel 214, which can send signals to a preamp 216 to be written to the disk 202, and can send servo signals to the microprocessor 220. The disk controller 228 can also include a memory controller to interface with memory 218. Memory 218 can be DRAM, which in some embodiments can be used as a buffer memory. In alternate embodiments, it is possible for the buffer memory to be implemented in the SRAM 210.

Although shown as separate components, the VCM driver 208 and spindle motor driver 212 can be combined into a single “power controller.” It is also possible to include the spindle control circuitry in that chip. The microprocessor 220 is shown as a single unit directly communicating with the VCM driver 208, although a separate VCM controller processor (not shown) may be used in conjunction with processor 220 to control the VCM driver 208. Further, the processor 220 can directly control the spindle motor driver 212, as shown. Alternatively, a separate spindle motor controller processor (not shown) can be used in conjunction with microprocessor 220.

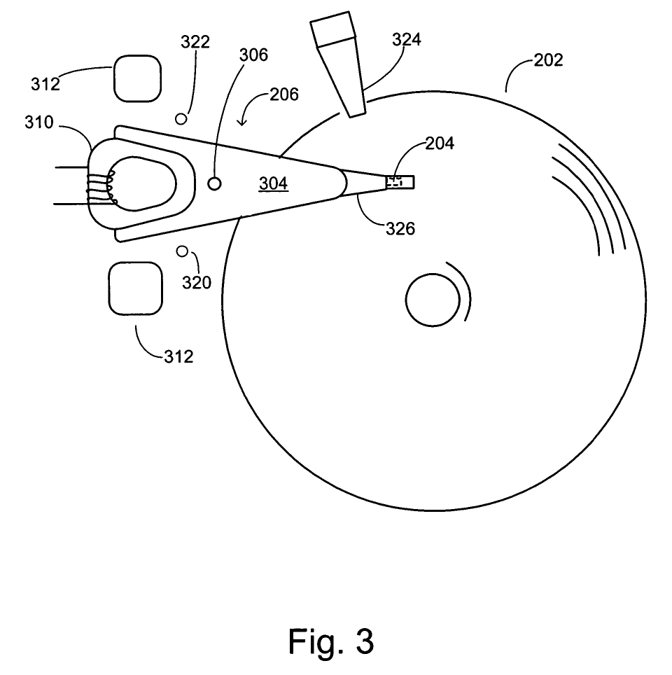

FIG. 3 shows some additional details of the actuator assembly 206. The actuator assembly 206 includes an actuator arm 304 that is positioned proximate the disk 202, and pivots about a pivot point 306 (e.g., which may be an actuator shaft). Attached to the actuator arm 304 is the read/write head 204, which can include one or more transducers for reading data from and writing data to a magnetic medium, an optical head for exchanging data with an optical medium, or another suitable read/write device. Also, attached to the actuator arm 304 is an actuator coil 310, which is also known as a voice coil or a voice actuator coil. While the actuator assembly discussed herein is a rotating actuator assembly, in alternate embodiments, a linear actuator can also be used.

The voice coil 310 moves relative to one or more magnets 312(only partially shown) when current flows through the voice coil 310. The magnets 312 and the actuator coil 310 are parts of the voice coil motor (VCM) 230, which applies a force to the actuator arm 304 to rotate it about the pivot point 306. The actuator arm 304 includes a flexible suspension member 326 (also known simply as a suspension). At the end of the suspension 326 is a mounted slider (not specifically shown) with the read/write head 204.

The VCM driver 208, under the control of the microprocessor 220 (or a dedicated VCM controller, not shown) guides the actuator arm 304 to position the read/write head 204 over a desired track, and moves the actuator arm 304 up and down a load/unload ramp 324. A latch (not shown) will typically hold the actuator arm 304 when in the parked position. The drive 115 also includes crash stops 320 and 322. Additional components, such as a disk drive housing, bearings, etc. which have not been shown for ease of illustration, can be provided by commercially available components, or components whose construction would be apparent to one of ordinary skill in the art reading this disclosure.

The actuator assembly sweeps an arc between the inner and outer diameters of the disk 202, that combined with the rotation of the disk 202 allows a read/write head 204 to access approximately an entire surface of the disk 202. The head 204 reads and/or writes data to the disks 202, and thus, can be said to be in communication with a disk 202 when reading or writing to the disk 202. Each side of each disk 202 can have an associated head 204, and the heads 204 are collectively arranged within the actuator assembly such that the heads 204 pivot in unison. In alternate embodiments, the heads can pivot independently. In the case of magnetic disk drives, the spinning of the disk 202 creates air pressure beneath the slider to form a micro-gap of typically less than one micro-inch between the disk 202 and the head 204.

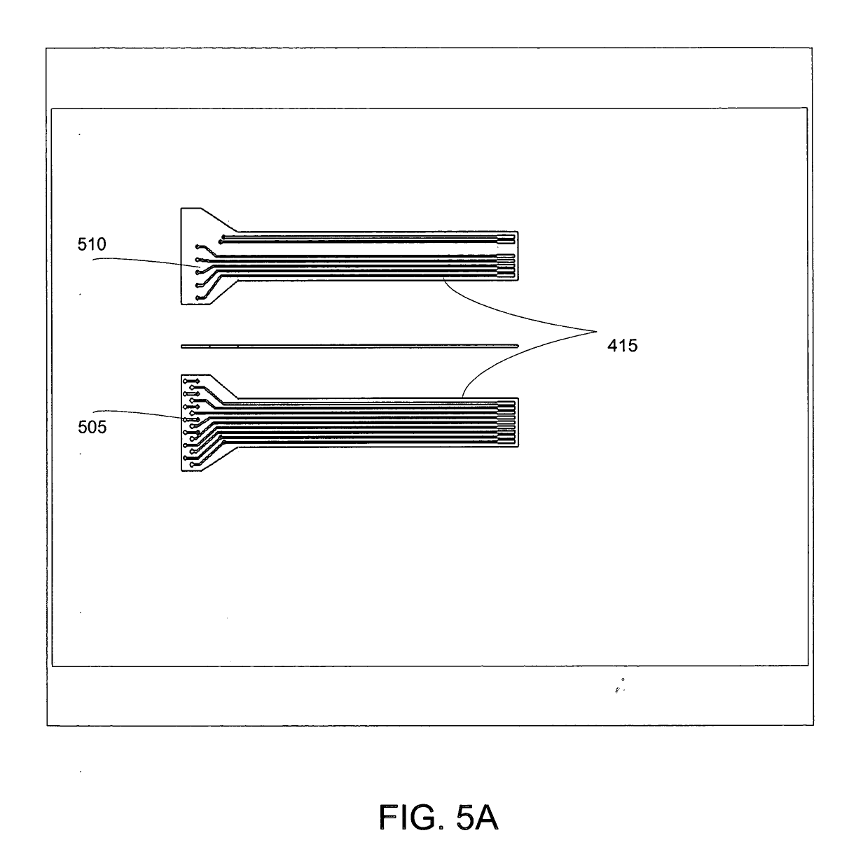

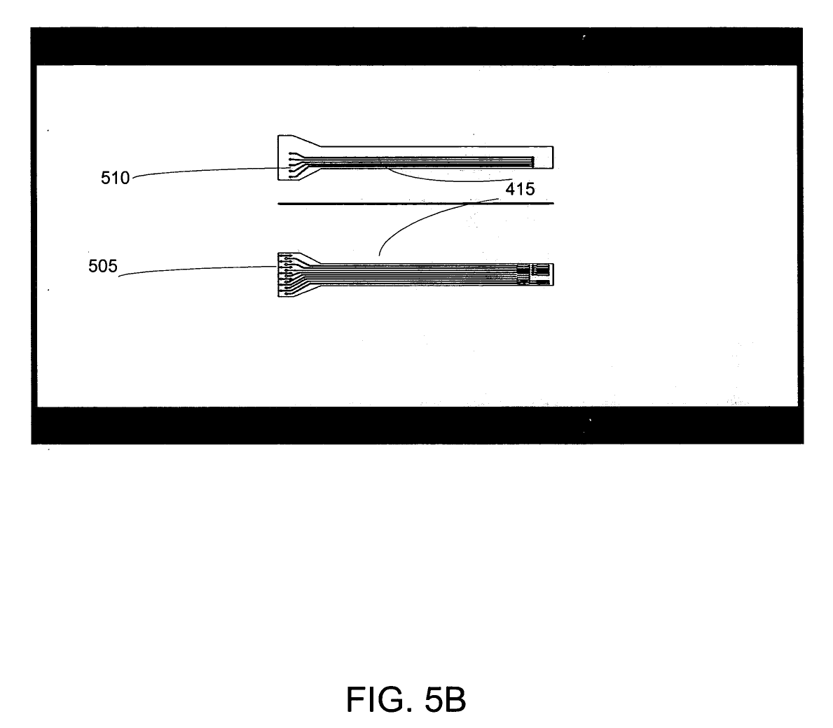

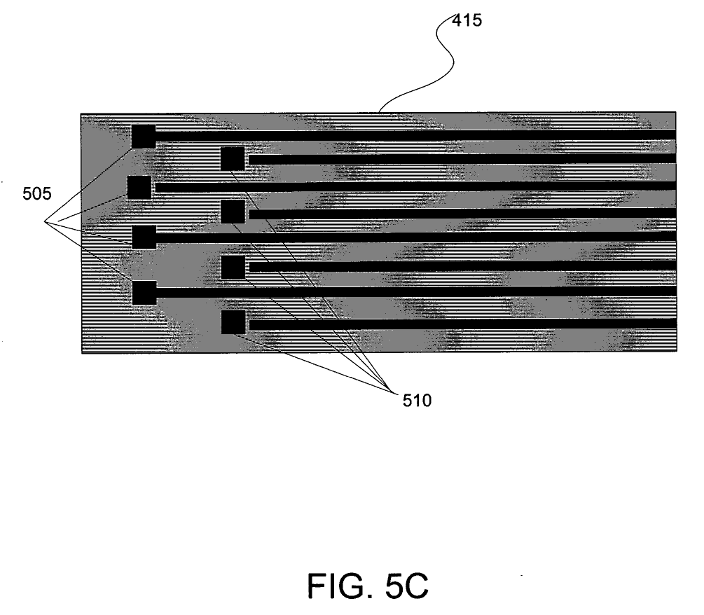

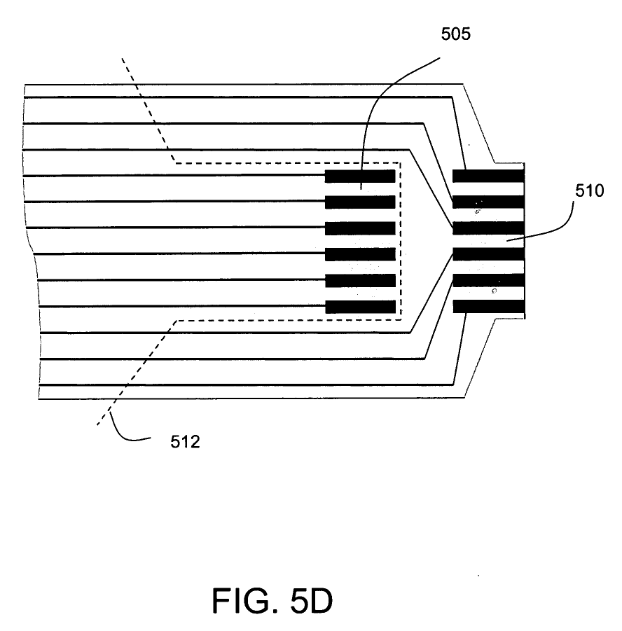

FIG. 4A is diagram illustrating a closer view of the connection between an array interface 118, a hard drive 115, and the array 110. In some embodiments, the hard drive is connected to the array interface 118 with a connector 415 for transferring data between the drive and the array. The connector 415 can be a flexible ribbon that includes a plurality of leads that are used to carry signals between the hard drive 115 and the array interface 118. While in the present embodiment, a flexible ribbon is disclosed, in alternate embodiments, a rigid connector can be used. The connector 415 can be designed as part of the hard drive 115 (i.e. attached to the hard drive during a manufacturing process) or as a separate flexible ribbon which can be disconnected from the hard drive 115. The end of the ribbon includes a set of pads that are organized in a line and are disclosed in greater detail in FIGS. 5A-5D. The end of the connector 415 is inserted into a connector on the array interface 118.

In one embodiment, the array interface is a circuit board that is connected to the array 110. In some embodiments, the array interface 118 is a “carrier” circuit board that is attached to the hard drive, remains with it during its life in manufacturing and engineering, and plugs into the array to mate with an interface. The circuit board can include a mount on which the hard drive 115 can be set and which is disclosed in greater detail with respect to FIG. 4B. The array interface 118, in this embodiment, includes an RS-232 level converter 430, which handles level shifting between the low voltage signals from the flexible circuit 415 to the combination connector 455. In addition, the array interface 118 in this embodiment includes a serial flash 425. The serial flash 425 can be used to store test instructions for the hard drive 115 as well as test results. Having the flash 425 available on the array interface 118 gives greater capability to the hard drive during testing but saves the cost of shipping the flash 425 with each drive 115.

The connector 415 ends with a standard set of connections that are used to connect the hard drive 115 to a host device interface such as an IDE interface, SCSI interface, secure digital interface 440, or an MMC interface. The connections include power 450 connections. The connections also include a second set of traces and contacts that are used for testing. These traces and contacts can include a serial interface 445, a connection 435 to the flash memory 425, and any other connections that might be useful during the manufacturing phase.

In one embodiment, the connector 415 is a specialized integrated connector that includes a Secure Digital (SD) 440 connection for transmitting data, a serial connection 445 that interfaces to the array interface 108, a serial flash connection 435 for communicating test instructions and results, and power connections 450. Lines for transmitting the SD, serial port, serial flash, and power can be built into the ribbon 415.

The array interface 118 is connected back to the array through a combination connector 455. The combination connector 455 is an integrated connector that combines test information from the serial ports 108 and power from the power supply 117 so that it can be provided to the hard drive 115. The combination connector can comprise a single port with integrated lines for the above signal or multiple ports (serial, data, etc).

FIG. 4B is a diagram illustrating one embodiment of a connection between an array interface carrier board 118 and an array base 465. Each of the ports on the array 110 includes an array base 465, a circuit board through which the array interface 118 connects to the array 110. In the present embodiment, the array base includes a board connector slot 468, into which the array interface 118 can be slid, though in alternate embodiments, other connections can be used. The board connector is used to transmit power and test instructions to the array interface board 118.

The array base 465 includes serial 470 and power 480 connectors. The serial 470 connector is used to receive test instructions from the serial port 108, which are then passed to the array interface 118 through the board connector slot 468. Similarly, the power connector 480 receives power from the power supply 117, which is provided to the array interface 118 through the board connector 468.

The array interface includes one or more connector pins 482 that are part of the combination connector 455, for receiving power and data through the board connector 468. While connector pins are used in the current embodiment, in alternate embodiments, the connection can be achieved through other means. The array interface 118 also includes a flex connector 484 for accepting the connector 415 from the hard drive. The flex connector 484 includes pins/inputs for transmitting power and data to the hard drive 115. Additionally, the hard drive, when connected can be stored on a drive mount 490. The drive mount 490 is configured to hold the hard drive during the testing process. The drive mount 490 can include a securing mechanism for holding the hard drive 115 to the array interface. After the testing process is finished, the hard drive 115 can be disconnected from the drive mount 490.

FIGS. 5A-5D illustrate various embodiments of a flexible ribbon and connector for linking a hard drive and an array interface, with FIGS. 5A and 5B including both top and bottom views. A first set of connector pads 505 is configured for use with a host device. These connector pads are used for transferring data during storage and retrieval operations performed by the host or the test system 105. The pads are configured to enable the hard drive to interface with a standardized host interface such as IDE, SCSI, SDIO, or MMC. In this example, an SDIO interface is illustrated.

A second set of pads 510 is configured for manufacturing processes. The pads 510 are used to accept and transmit data during a testing and configuration phase. For example, the pads can include pins for a serial connection and pins for accessing the flash memory 425. While in the present embodiment, the connector uses pads, in alternate embodiments, other connection mechanisms can be used. The pads can be rectangular protrusions that enclose prongs.

The version shown in FIG. 5A has the manufacturing connections 510 on one side of the flexible circuit and customer (i.e. normal non-testing use) interface connections 505 on the other side of the flexible circuit. In this case, the flexible circuit is inserted into a mating connector with the desired interface on the “top” (visible to the user) side. During manufacturing tests, the manufacturing connection 510 is on the “top”. When the customer uses the drive, the customer connection 505 is on the “top”.

The version shown in FIG. 5B has both the manufacturing and customer connections terminating on the same side of the flexible circuit (bottom view of FIG. 5B). In manufacturing, the flexible circuit is used as shown. Before shipping to the customer, the rightmost contacts can be cut off leaving only the terminating fingers for the customer interface—SDIO in this example.

In FIG. 5C, both sets of pads are located on the same side of the connector with the customer set of pads 505 being closer to the end of the flexible circuit than the pads used in manufacturing 510. FIG. 5D is similar to FIG. 5C in that all of the connections are on a single side of the flexible circuit. In addition, the circuit of FIG. 5D includes a cut line 512 that enables the manufacturing pads 510 to be cut away after testing.

Other features, aspects and objects of the invention can be obtained from a review of the figures and claims. It is to be understood that other embodiments of the invention can be developed and fall within the spirit and scope of the invention and claims.

The foregoing description of preferred embodiments of the present invention has been provided for the purposes of illustration and description. It is not intended to be exhaustive or to limit the invention to the precise forms disclosed. Obviously, many modifications and variations will be apparent to the practitioner skilled in the art. The embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the following claims and their equivalence.

In addition to an embodiment consisting of specifically designed integrated circuits or other electronics, the present invention may be conveniently implemented using a conventional general purpose or a specialized digital computer or microprocessor programmed according to the teachings of the present disclosure, as will be apparent to those skilled in the computer art.

Appropriate software coding can readily be prepared by skilled programmers based on the teachings of the present disclosure, as will be apparent to those skilled in the software art. The invention may also be implemented by the preparation of application specific integrated circuits or by interconnecting an appropriate network of conventional component circuits, as will be readily apparent to those skilled in the art.

The present invention includes a computer program product which is a storage medium (media) having instructions stored thereon/in which can be used to program a computer to perform any of the processes of the present invention. The storage medium can include, but is not limited to, any type of disk including floppy disks, optical discs, DVD, CD-ROMs, microdrive, and magneto-optical disks, ROMs, RAMs, EPROMs, EEPROMs, DRAMs, VRAMs, flash memory devices, magnetic or optical cards, nanosystems (including molecular memory ICs), or any type of media or device suitable for storing instructions and/or data.

Stored on any one of the computer readable medium (media), the present invention includes software for controlling both the hardware of the general purpose/specialized computer or microprocessor, and for enabling the computer or microprocessor to interact with a human user or other mechanism utilizing the results of the present invention. Such software may include, but is not limited to, device drivers, operating systems, and user applications.

Included in the programming (software) of the general/specialized computer or microprocessor are software modules for implementing the teachings of the present invention.

What is claimed:

1. A connector for connecting an embedded media device to a host device, the connector comprising:
a connective strip comprising a plurality of traces, a near end and a far end, the far end opposite the near end, the connective strip coupled to the media device at the near end;
a first set of pins configured at the far end of the connective strip; and
a second set of pins configured between the first set of pins and the near end, the second set of pins configured for use during a manufacturing process.

2. The connector of claim 1, wherein the second set of pins is configured closer to the near end than to the first set of pins.

3. The connector of claim 1, wherein the second set of pins is configured closer to the first set of pins than to the near end.

4. The connector of claim 1, wherein the second set of pins is configured sufficiently close to the first set of pins so as to enable the first and second sets of pins to connect to a single external connection.

5. The connector of claim 1, wherein the connector comprises one or more pads for the first set of pins.

6. The connector of claim 1, wherein the connector comprises one or more pads for the second set of pins.

7. The connector of claim 1, wherein the connector is configured to enable the embedded media device to function within a cell phone.

8. The connector of claim 1, wherein the connector is configured to enable the embedded media device to function within a personal data assistant(PDA).

9. The connector of claim 1, wherein the connector is configured to enable the embedded media device to function within a media player.

10. The connector of claim 1, wherein the second set of pins is configured for use in testing the media device.

11. The connector of claim 1, wherein the second set of pins is configured to accept configuration information for the embedded media device.

12. A media device, configured to function as an embedded media device within a portable device, the media device comprising:
one or more rotatable storage media for storing data;
a read/write mechanism for reading from and writing to the one or more rotatable storage media; and
a connector for connecting the media device to the portable device, the connector comprising:
a connective strip comprising a plurality of traces, a near end, and a far end opposite the near end, the connective strip coupled to the media device at the near end;
a first set of pins configured at the far end of the connective strip; and
a second set of pins configured between the first set of pins and the near end, the second set of pins configured for use during a manufacturing process.

13. A connector for connecting an embedded media device to a host device, the connector comprising:
a connective strip comprising a plurality of traces, a near end, a far end, a top side, and a bottom side, the far end opposite the near end, the connective strip coupled to the media device at the near end;
a first set of pins configured at the top side and the far end of the connective strip;
and
a second set of pins, the second set of pins configured for use during a manufacturing process, the second set of pins configured at the bottom side and the far end of the connective strip.

14. The connector of claim 13, wherein the connector comprises one or more pads for the first set of pins.

15. The connector of claim 13, wherein the connector comprises one or more pads for the second set of pins.

16. The connector of claim 13, wherein the connector is configured to enable the embedded media device to function within a cell phone.

17. The connector of claim 13, wherein the connector is configured to enable the embedded media device to function within a personal data assistant (PDA).

18. A system for hard drive testing, the system comprising:
a hard drive comprising:
a rotatable storage medium;
a read/write mechanism for writing to and reading from the rotatable storage medium; and
a connector for connecting the hard drive to external devices, the connector comprising:
a connective strip comprising a plurality of traces;
a first set of pins configured at a far end of the connective strip; and
a second set of pins configured for use during a manufacturing process; and
a testing board coupled to the hard drive through the second set of pins, the testing board comprising:
a memory for storing testing instructions for the hard drive for use during the manufacturing process; and
a securing mechanism for holding the hard drive to the testing board.

19. The system of claim 18, wherein the memory comprises a flash memory.

20. The system of claim 18, wherein the testing board is coupled to a testing array.

21. The system of claim 20, wherein the testing board receives the testing instructions from the testing array.

22. The system of claim 18, wherein the connective strip comprises traces for a serial connection.

23. The system of claim 18, wherein the connective strip comprises traces for a Secure Digital Input Output (SDIO) connection.
